(19) United States
(12) Patent Application Publication
(10) Pub. No.: US 2022/0272836 A1
(43) Pub. Date: Aug. 25, 2022

(54) FLEXIBLE PRINTED WIRING BOARD AND BATTERY WIRING MODULE

(71) Applicants: SUMITOMO ELECTRIC PRINTED CIRCUITS, INC., Koka-shi, Shiga (JP); SUMITOMO ELECTRIC INDUSTRIES, LTD., Osaka-shi, Osaka (JP); SUMITOMO WIRING SYSTEMS, LTD., Yokkaichi, Mie (JP); AUTONETWORKS TECHNOLOGIES, LTD., Yokkaichi, Mie (JP)

(72) Inventors: Yoshifumi UCHITA, Koka-shi (JP); Shinichi TAKASE, Yokkaichi (JP)

(73) Assignees: SUMITOMO ELECTRIC PRINTED CIRCUITS, INC., Koka-shi, Shiga (JP); SUMITOMO ELECTRIC INDUSTRIES, LTD., Osaka-shi, Osaka (JP); SUMITOMO WIRING SYSTEMS, LTD., Yokkaichi, Mie (JP); AUTONETWORKS TECHNOLOGIES, LTD., Yokkaichi, Mie (JP)

(21) Appl. No.: 17/624,972

(22) PCT Filed: Jul. 9, 2020
(86) PCT No.: PCT/JP2020/026937

§ 371 Date: Jan. 5, 2022

(30) Foreign Application Priority Data
Jul. 10, 2019 (JP) 2019-128676

(51) Int. Cl. H05K 1/02; H05K 3/28; H05K 1/11; H01M 50/519

(52) U.S. Cl. CPC H05K 1/0256; H05K 3/288; H05K 1/118; H01M 50/519; H05K 3/06

(57) ABSTRACT

A flexible printed wiring board according to an aspect includes an insulating base film, a conductive pattern disposed on one surface of the base film and including one or more land portions, and a solder resist layer disposed on one surface of the base film in a partial or any region excluding the one or more land portions, the solder resist layer having a CTI value of 200 V or more.

### TECHNICAL FIELD

The present disclosure relates to a flexible printed wiring board and a battery wiring module. This application claims priority based on Japanese Patent Application No. 2019-128676 filed on Jul. 10, 2019. The entire contents of the description in this Japanese patent application are incorporated herein by reference.

### BACKGROUND ART

In recent years, many systems have been made electronic and miniaturized. Along with this, there is an increasing expectation for printed wiring boards. Inter alia, a flexible printed wiring board that is flexible and can be mounted compactly has attracted attention.

Some of such systems are of high power supply voltage, and the printed wiring board is required to have high insulation corresponding thereto. A comparative tracking index (CTI) is used as an index for insulation. When the CTI value is low, a minimum pitch for wiring cannot be narrowed from the viewpoint of insulation, resulting in reduced mounting efficiency.

An inflexible, rigid printed wiring board can have increased insulation as a whole by using as its base substrate a base substrate having a high CTI value. Similarly, as a base film used for a flexible printed wiring board, for example, an aramid film has been proposed (see Japanese Patent Laid-Open No. 11-049876). The publication describes that for the aramid film an amount of chlorine is controlled to provide an increased CTI value.

### CITATION LIST

### Patent Literature

PTL 1: Japanese Patent Laid-Open No. 11-049876

### SUMMARY OF INVENTION

According to an aspect of the present disclosure a flexible printed wiring board comprises an insulating base film, a conductive pattern disposed on one surface of the base film and including one or more land portions, and a solder resist layer disposed on one surface of the base film in a partial or any region excluding the one or more land portions, the solder resist layer having a CTI value of 200 V or more.

### BRIEF DESCRIPTION OF DRAWINGS

FIG. 1 is a schematic cross-sectional view of a flexible printed wiring board according to an embodiment of the present disclosure.

FIG. 2 is a plan view of a battery wiring module 100.

### DETAILED DESCRIPTION

### Problem to be Solved by the Present Disclosure

The above-described conventional base film, however, has a CTI value of about 150 V at maximum. Therefore, a flexible printed wiring board formed using the conventional base film does not have sufficiently high insulation and imposes a limitation on narrowing a pitch of wiring. For this reason, there is a demand for a flexible printed wiring board with further enhanced insulation.

A flexible printed wiring board's insulation may be enhanced for example as follows: a high CTI layer using a base substrate material known to have a high CTI value for a rigid printed wiring board is disposed on a surface of a base film so that the base film has a two-layer structure. In this method, however, the base film becomes thick, and in addition, a most significant feature of a flexible printed wiring board, i.e., flexibility, would be reduced by the high CTI layer.

The present disclosure has been made in view of such circumstances as described above, and contemplates a flexible printed wiring board having enhanced insulation while preventing reduction in flexibility.

### Advantageous Effect of the Present Disclosure

The presently disclosed flexible printed wiring board can have enhanced insulation while preventing reduction in flexibility.

### DESCRIPTION OF EMBODIMENTS OF THE PRESENT DISCLOSURE

As a result of intensive studies by the present inventors on improvement in insulation of a flexible printed wiring board, it has been found that, while conventionally it has been believed that a base film needs to have a surface entirely having a high CTI, covering a spacing between conductive patterns with a high CTI layer allows a flexible printed wiring board to have increased insulation as a whole. In other words, the present inventors have completed the present disclosure by noting that a flexible printed wiring board's insulation can be enhanced by increasing a CTI of a solder resist layer covering a spacing between conductive patterns, rather than increasing a CTI of a base film.

That is, a flexible printed wiring board in an aspect of the present disclosure made in order to solve the above-described problem comprises: an insulating base film; a conductive pattern disposed on one surface of the base film and including one or more land portions; and a solder resist layer disposed on one surface of the base film in a partial or any region excluding the one or more land portions, the solder resist layer having a CTI value of 200 V or more.

The flexible printed wiring board including a solder resist layer having a CTI value equal to or larger than the above specified lower limit, is excellently insulating. The flexible printed wiring board can thus have wiring with a reduced pitch. Further, the flexible printed wiring board eliminates the necessity of introducing an additional layer for enhancing insulation, and can thus prevent reduction in flexibility.

The solder resist layer preferably has an average thickness of 10 μm or more and 50 μm or less. Setting the average thickness of the solder resist layer within the above specified range enables high CTI while preventing reduction in flexibility.

The conductive pattern includes a wiring portion having a minimum pitch preferably of 30 μm or more and 900 μm or less. Setting the minimum pitch of the wiring portion included in the conductive pattern within the above specified range enables an increased mounting density while maintaining insulation between wiring portions.

A “CTI value” as referred to herein indicates a value measured in conformity to JIS-C-2134:2007. A “land portion” as referred to herein indicates a portion of wiring that is increased in size to allow solder connection to be performed for mounting an electronic component in a conductive pattern in the middle of circuitry.

A “major component” as referred to herein indicates a component having a largest content, for example, a component having a content of 50% by mass or more. A “minimum pitch of a wiring portion” as referred to herein indicates a distance between a central axis of wiring and that of adjacent wiring when wiring formed by a conductive pattern is disposed in a straight line in layers in a closest-packed manner.

### DETAILED DESCRIPTION OF EMBODIMENTS OF THE PRESENT DISCLOSURE

Hereinafter, the presently disclosed flexible printed wiring board will be described in detail with reference to the drawings.

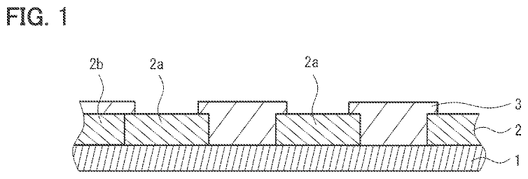

FIG. 1 shows a flexible printed wiring board including a base film 1, a conductive pattern 2, and a solder resist layer 3.

<Base Film>

Base film 1 is a member supporting conductive pattern 2, and is a structural member ensuring that the flexible printed wiring board has strength. Base film 1 is insulating and flexible.

Base film 1 can for example have as a major component thereof polyimide, a liquid crystal polymer represented by liquid crystal polyester, polyethylene terephthalate, polyethylene naphthalate, polyphenylene ether, fluororesin and other similar soft materials, paper phenol, paper epoxy, glass composite, glass epoxy, a glass substrate and other similar hard materials, a rigid flexible material obtained by compositing the soft material and the hard material, and the like. Inter alia, polyimide is preferable as it is excellent in heat resistance and flexibility. Base film 1 may be porous or may contain a filler, an additive or the like.

While base film 1 is not particularly limited in thickness, base film 1 has an average thickness with a lower limit preferably of 5 μm, more preferably 12 μm. Base film 1 has the average thickness with an upper limit preferably of 500 μm, more preferably 200 μm. When the average thickness of base film 1 is less than the lower limit, base film 1 may be insufficient in strength. When the average thickness of base film 1 exceeds the upper limit, the flexible printed wiring board may be insufficiently flexible.

<Conductive Pattern>

Conductive pattern 2 constitutes a structure such as an electric wiring structure, a ground, and a shield. Conductive pattern 2 is disposed on one surface of base film 1 and includes a plurality of land portions 2a and a wiring portion 2b connecting to land portion 2a.

While conductive pattern 2 is not particularly limited in what material it is formed of insofar as it is electrically conductive, the material includes metals such as copper, aluminum and nickel for example, and generally, copper is used as it is relatively inexpensive and has high conductivity. Conductive pattern 2 may have a plated surface.

Conductive pattern 2 has an average thickness with a lower limit preferably of 2 μm, more preferably 5 μm. Conductive pattern 2 has the average thickness with an upper limit preferably of 100 μm, more preferably 70 μm. When the average thickness of conductive pattern 2 is less than the lower limit, conductive pattern 2 may be insufficiently conductive. When the average thickness of the conductive pattern 2 exceeds the upper limit, the flexible printed wiring board becomes unnecessarily thick and may be reduced in flexibility. Although conductive pattern 2 may have land portion 2a and wiring portion 2b differently in average thickness, land portion 2a and wiring portion 2b preferably have the same average thickness from the viewpoint of ease of manufacture.

Land portion 2a included in conductive pattern 2 is appropriately determined in size depending on the electronic component mounted on land portion 2a.

Wiring portion 2b included in conductive pattern 2 has an average width with a lower limit preferably of 2 μm, more preferably 5 μm. Wiring portion 2b has the average width with an upper limit preferably of 20 μm, more preferably 15 μm. When the average width of wiring portion 2b is less than the lower limit, conductive pattern 2 may be insufficiently conductive. When the average width of wiring portion 2b exceeds the upper limit, conductive pattern 2 is implemented less densely, which may make it difficult to mount electronic components at high density.

Wiring portion 2b included in conductive pattern 2 has a minimum pitch with a lower limit preferably of 30 μm, more preferably 50 μm, still more preferably 100 μm. Wiring portion 2b has the minimum pitch with an upper limit preferably of 900 μm, more preferably 500 μm. When the minimum pitch of wiring portion 2b is less than the lower limit, and high voltage is applied, dielectric breakdown may be caused. The minimum pitch of wiring portion 2b exceeding the upper limit may makes it difficult to mount electronic components at high density.

<Solder Resist Layer>

Solder resist layer 3 protects conductive pattern 2 against external force, moisture, and the like. In the flexible printed wiring board, solder resist layer 3 improves the insulation of the flexible printed wiring board. Solder resist layer 3 is disposed on one surface of base film 1 in a partial or any region excluding land portion 2a. That is, the flexible printed wiring board has base film 1 externally unexposed.

Solder resist layer 3 can for example be of a photosensitive solder resist, a thermosetting solder resist, a dry film-type solder resist, or the like.

Solder resist layer 3 can contain epoxy resin, polyimide, silicone resin and the like as a major component. Inter alia, epoxy resin is preferable as it can easily increase the CTI value.

Solder resist layer 3 has an average thickness with a lower limit preferably of 10 μm, more preferably 15 μm. Solder resist layer 3 has the average thickness with an upper limit preferably of 50 μm, more preferably 45 μm. When the average thickness of solder resist layer 3 is less than the lower limit, the flexible printed wiring board may be insufficiently insulating. When the average thickness of solder resist layer 3 exceeds the upper limit, the flexible printed wiring board becomes unnecessarily thick and may be reduced in flexibility. The “average thickness of the solder resist layer” refers to an average value in thickness of a region of the solder resist layer located on a surface of the base film (and having a diameter of 1 mm or more), that is, a region excluding a portion thereof disposed on a surface of the conductive pattern.

Solder resist layer 3 is preferably larger in thickness than conductive pattern 2. Solder resist layer 3 larger in thickness than conductive pattern 2 more reliably prevents external exposure of base film 1. Thus preventing external exposure of base film 1 ensures that the flexible printed wiring board is insulating.

When solder resist layer 3 is larger in thickness than conductive pattern 2, solder resist layer 3 and conductive pattern 2 have a difference in average thickness with an upper limit preferably of 20 μm, more preferably 15 μm. When the difference in average thickness exceeds the upper limit, the flexible printed wiring board becomes unnecessarily thick and may be reduced in flexibility. The lower limit for the difference in average thickness is not particularly limited, and may be 0 μm.

When solder resist layer 3 is larger in thickness than conductive pattern 2, solder resist layer 3 may protrude on a surface of land portion 2a, as shown in FIG. 1, and cover a portion of the periphery of land portion 2a in the form of a strip. Solder resist layer 3 protruding on a surface of land portion 2a can prevent a gap from being formed between land portion 2a and solder resist layer 3. This further reliably prevents external exposure of base film 1.

When solder resist layer 3 covers a portion of the periphery of land portion 2a, solder resist layer 3 protrudes from land portion 2a by a distance on average with an upper limit preferably of 200 μm, more preferably 100 μm. When solder resist layer 3 protrudes from land portion 2a by a distance on average exceeding the above specified upper limit, land portion 2a has a reduced exposed portion, which may make it difficult to mount an electronic component and the like.

Solder resist layer 3 has a CTI value with a lower limit preferably of 200 V, more preferably 300 V, still more preferably 400 V, particularly preferably 450 V. When solder resist layer 3 has a CTI value less than the lower limit, the flexible printed wiring board may be insufficiently insulating. While the upper limit for the CTI value of solder resist layer 3 is not particularly limited, solder resist layer 3 normally has a CTI value of 700 V or less.

<Method for Manufacturing Flexible Printed Wiring Board>

The flexible printed wiring board can be manufactured in a manufacturing method including, for example, a conductive pattern forming step, a solder resist disposing step, and a land portion forming step.

(Conductive Pattern Forming Step)

In the conductive pattern forming step, for example, conductive pattern 2 is formed through the following procedure.

Initially, a conductor layer is formed on one surface of base film 1. The conductor layer can be formed, for example, by bonding a foil-shaped conductor using an adhesive, or by a known deposition technique. Examples of the conductor include copper, silver, gold and nickel. The adhesive is not particularly limited insofar as it can bond the conductor to base film 1, and various known adhesives can be used. Examples of the deposition technique include vapor deposition and plating. The conductor layer is preferably formed by adhering a copper foil to base film 1 using a polyimide adhesive.

Subsequently, the conductive layer is patterned to form conductive pattern 2. The conductor layer can be patterned in a known method, for example, by photo-etching. Photo-etching is performed by: forming a resist film having a predetermined pattern on one surface of the conductor layer; treating the conductor layer exposed from the resist film with etchant; and removing the resist film.

(Solder Resist Disposing Step)

In the solder resist disposing step, a solder resist is disposed so as to cover base film 1 and conductive pattern 2. Specifically, the solder resist is applied to a surface of base film 1 and conductive pattern 2.

After the solder resist is disposed, a coverlay including an insulating film having a back surface with an adhesive layer thereon may further be disposed. In this case, the solder resist is applied only to a portion where electronic circuitry or the like is mounted, and the coverlay is disposed on another region.

(Land Portion Forming Step)

In the land portion forming step, an opening to be land portion 2a is formed in the solder resist applied in the solder resist disposing step. The opening can be formed by punching using a punch and a die, laser processing, or the like. Solder resist layer 3 disposed in a partial or any region excluding land portion 2a can thus be formed.

<Advantages>

The flexible printed wiring board that includes solder resist layer 3 that has a CTI value equal to or larger than 200 V, is excellently insulating. The flexible printed wiring board can thus have wiring with a reduced pitch. Further, the flexible printed wiring board eliminates the necessity of introducing an additional layer for increasing insulation, and can thus prevent reduction in flexibility.

### OTHER EMBODIMENTS

It should be understood that the embodiments disclosed herein have been described for the purpose of illustration only and in a non-restrictive manner in any respect. The scope of the present invention is defined by the terms of the claims, rather than the configurations of the above embodiments, and is intended to include any modifications within the meaning and scope equivalent to the terms of the claims.

While in the above embodiment the conductive pattern is disposed only on one surface of the base film, the conductive pattern may be disposed on opposite surfaces of the base film. While in this case a solder resist layer having a CTI value of 200 V or more may be disposed on the opposite surfaces of the base film, the solder resist layer having a CTI value of 200 V or more may be disposed on only one surface of the base film for example when a high-voltage circuit is provided only on one surface of the base film.

When the flexible printed wiring board is divided into a high voltage region and a low voltage region, a solder resist layer having a CTI value of 200 V or more may be disposed only on the base film constituting the high voltage region.

While in the above embodiment there are a plurality of land portions, there may be provided a single land portion, rather than a plurality of land portions.

The presently disclosed flexible printed wiring board can thus have enhanced insulation while preventing reduction in flexibility. Even when mounting an electronic circuit which is high in voltage, the flexible printed wiring board that allows wiring to have a reduced pitch allows the electronic circuit to be miniaturized.

(Battery Wiring Module)

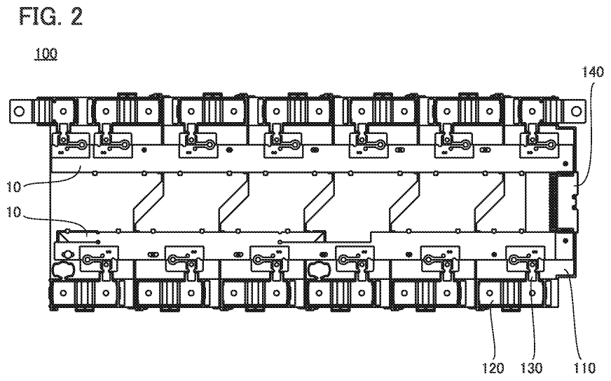

Hereinafter, a battery wiring module (hereinafter referred to as a “battery wiring module 100”) in one aspect of the present disclosure will be described. FIG. 2 is a plan view of battery wiring module 100. As shown in FIG. 2, battery wiring module 100 includes a flexible printed wiring board 10, an insulating protector 110, a bus bar 120, a relay member 130, and a connector 140. Flexible printed wiring board 10 is the flexible printed wiring board described above.

Insulating protector 110 is a plate-shaped member. Insulating protector 110 is formed of an insulating material. The insulating material is, for example, an insulating synthetic resin. Flexible printed wiring board 10 is mounted on an upper surface of insulating protector 110.

Bus bar 120 is a plate-shaped member formed of a conductive material. The conductive material is, for example, a metal material. Examples of the metal material include copper, a copper alloy, aluminum, an aluminum alloy, and stainless steel (SUS). Bus bar 120 is electrically connected to a power storage element (not shown). The power storage element is, for example, a secondary battery. Bus bar 120 connects any number of power storage elements in series or in parallel.

Relay member 130 is a plate-shaped member formed of a conductive material. The conductive material is, for example, a metal material. Examples of the metal material include copper, a copper alloy, aluminum, an aluminum alloy, stainless steel (SUS), nickel, and a nickel alloy. Relay member 130 electrically interconnects an extra length absorbing portion of flexible printed wiring board 10 and bus bar 120. Battery wiring module 100 may not include relay member 130. In this case, bus bar 120 is electrically connected to the extra length absorbing portion of flexible printed wiring board 10 without relay member 130 interposed. Battery wiring module 100 is electrically connected to an external device or the like by connector 140.

Thus the presently disclosed flexible printed wiring board is applicable to battery wiring module 100 attached to a power storage module including a power storage element.

### REFERENCE SIGNS LIST

1 base film, 2 conductive pattern, 2a land, 2b wiring portion, 3 solder resist layer, 100 battery wiring module, 110 insulating protector, 120 bus bar, 130 relay member, 140 connector, 10 flexible printed wiring board.

1. A flexible printed wiring board comprising:
an insulating base film;
a conductive pattern disposed on one surface of the base film and including one or more land portions; and
a solder resist layer disposed on one surface of the base film in a partial or any region excluding the one or more land portions,
the solder resist layer having a CTI value of 200 V or more.

2. The flexible printed wiring board according to claim 1, wherein the solder resist layer has an average thickness of 10 μm or more and 50 μm or less.

3. The flexible printed wiring board according to claim 1, wherein the conductive pattern includes a wiring portion having a minimum pitch of 30 μm or more and 900 μm or less.

4. A battery wiring module comprising the flexible printed wiring board according to claim 1 and attached to a battery module mounted in a vehicle.
